(19) United States
(12) Patent Application Publication
(10) Pub. No.: US 2025/0151442 A1
(43) Pub. Date: May 8, 2025

(54) IMAGE SENSOR

(71) Applicant: Commissariat à l'Énergie Atomique et aux Énergies Alternatives, Paris (FR)

(72) Inventor: Olivier Saxod, Grenoble (FR)

(73) Assignee: Commissariat à l'Énergie Atomique et aux Énergies Alternatives, Paris (FR)

(21) Appl. No.: 18/933,231

(22) Filed: Oct. 31, 2024

(30) Foreign Application Priority Data
Nov. 6, 2023 (FR) 2312004

(51) Int. Cl. H01L 27/146

(52) U.S. Cl. CPC H10F 39/807

(57) ABSTRACT

An image sensor including a plurality of pixels formed inside and on top of a semiconductor substrate, each pixel including: a photosensitive area formed in the semiconductor substrate; a peripheral insulating trench vertically extending in the semiconductor substrate from an upper surface of the semiconductor substrate and laterally delimiting the photosensitive area; a charge collection area; a transfer region located in the semiconductor substrate and vertically extending between the charge collection area and the photosensitive area; and a transfer gate vertically extending in the semiconductor substrate, from the upper surface of the semiconductor substrate and inside of the peripheral insulating trench, deeper than the charge collection area, wherein the transfer region is doped with a same first conductivity type as the photosensitive area and has a doping level lower than that of the photosensitive area.

### CROSS REFERENCE TO RELATED APPLICATIONS

This application claims priority to French application number 2312004, filed Nov. 6, 2023. The contents of this application is incorporated by reference in its entirety.

### TECHNICAL FIELD

The present disclosure generally concerns electronic devices, more particularly image sensor pixels.

### PRIOR ART

Image sensor pixels, each comprising a photosensitive area formed in a semiconductor substrate, adapted to converting light into electron-hole pairs, have been provided. During a phase of exposure of the sensor, photogenerated charges (electrons or holes) accumulate in the photosensitive area. During a subsequent readout phase, a charge transfer device is controlled to transfer the photogenerated charges accumulated in the photosensitive area to a charge collection area.

US patent application 2021/0020675 describes examples of such pixels. In this application, each pixel more precisely comprises a photosensitive area formed in a semiconductor substrate and laterally bordered by a peripheral insulating trench. Each pixel further comprises a charge collection area laterally interposed between a vertical transfer gate, formed in the peripheral insulating trench, and an implanted region formed in the semiconductor substrate above the photosensitive area. The photosensitive area and the charge collection area are P-type doped, and the implanted region is N-type doped. In this example, a P-doped transfer region having a doping level equal to that of the photosensitive area is vertically interposed between the photosensitive area and the charge collection area. By applying a potential to the vertical transfer gate of the pixel, a potential barrier may be formed in the transfer region, between the vertical transfer gate and the implanted N-type region. This image sensor pixel however exhibits various disadvantages, particularly due to the fact that it is difficult to form the N-type implanted region in precise fashion. This complicates the decreasing of the pitch of the pixels of the image sensor. Further, pixels of this type have a relatively high dark current, that it would be desirable to decrease.

### SUMMARY OF THE INVENTION

There exists a need to overcome all or part of the disadvantages of image sensor pixels and of known image sensors. It would in particular be desirable to decrease the pixel dimensions, to enable the forming of image sensors having pixel pitches smaller than those of existing image sensors.

For this purpose, an embodiment provides an image sensor comprising a plurality of pixels formed inside and on top of a semiconductor substrate, each pixel comprising:
a photosensitive area formed in the semiconductor substrate;
a peripheral insulating trench vertically extending in the semiconductor substrate, from an upper surface of the semiconductor substrate, and laterally delimiting the photosensitive area;
a charge collection area;
a transfer region located in the semiconductor substrate and vertically extending between the charge collection area and the photosensitive area; and
a transfer gate vertically extending in the semiconductor substrate, from the upper surface of the semiconductor substrate and inside of the peripheral insulating trench, deeper than the charge collection area,
wherein the transfer region is doped with a same first conductivity type as the photosensitive area and has a doping level lower than that of the photosensitive area.

According to an embodiment, the transfer gate vertically extends in the semiconductor substrate down to a depth substantially equal to that of the transfer region.

According to an embodiment, the photosensitive area and the transfer region have a substantially horizontal interface.

According to an embodiment, the charge collection area is doped with the first conductivity type and has a doping level higher than that of the transfer region.

According to an embodiment, the sensor further comprises a doped well of a second conductivity type opposite to the first conductivity type, the well vertically extending in the semiconductor substrate from the upper surface of the semiconductor substrate down to a depth smaller than that of the transfer gate.

According to an embodiment, the sensor further comprises an electrically-insulating trench laterally interposed between the charge collection area and the well.

According to an embodiment, the electrically-insulating trench vertically extends in the semiconductor substrate, from the upper surface of the semiconductor substrate, down to a depth greater than that of the charge collection area.

According to an embodiment, the charge collection area and the well are adjacent.

According to an embodiment, the peripheral insulating trench and the transfer gate respectively comprise first and second electrically-conductive regions, the first electrically-conductive region being electrically insulated from the second electrically-conductive region.

According to an embodiment, the second electrically-conductive region is flush with the upper surface of the semiconductor substrate.

According to an embodiment, the second electrically-conductive region is separated from the upper surface of the semiconductor substrate by a non-zero thickness of insulating material.

According to an embodiment, the transfer gate is common to two pixels.

According to an embodiment, the transfer gate is common to four pixels.

According to an embodiment, the first conductivity type is type N.

According to an embodiment, the sensor further comprises a control circuit configured to alternately apply to the transfer gate:
a first potential adapted to blocking a charge transfer from the photosensitive area to the charge collection area; and
a second potential, different from the first potential, adapted to allowing a charge transfer from the photosensitive area to the charge collection area.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A and FIG. 1B are simplified and partial views, respectively a top view and a cross-section view along plane BB of FIG. 1A, of an example of an image sensor pixel according to an embodiment;

FIG. 2A and FIG. 2B are simplified and partial views, respectively a top and a cross-section view along plane BB of FIG. 2A, of an example of an image sensor pixel according to an embodiment;

FIG. 3A and FIG. 3B are simplified and partial views, respectively a top and a cross-section view along plane BB of FIG. 3A, of an example of an image sensor pixel according to an embodiment;

FIG. 4 is a top view, simplified and partial, of an arrangement of two adjacent pixels according to an embodiment; and

FIG. 5 is a top view, simplified and partial, of an arrangement of four adjacent pixels according to an embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the methods of manufacturing image sensor pixels have not been detailed, the described embodiments and variants being compatible with usual image sensor pixel manufacturing methods. Further, the circuits (transistors and connections) of the pixels have not been detailed, the described embodiments and variants being compatible with usual pixel circuits. Further, the readout circuits, or column decoders, the control circuits, or line decoders, and the applications in which image sensors can be provided have not been detailed, the described embodiments and variants being compatible with the readout circuits and the control circuits of usual image sensors, as well as with usual applications implementing image sensors.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

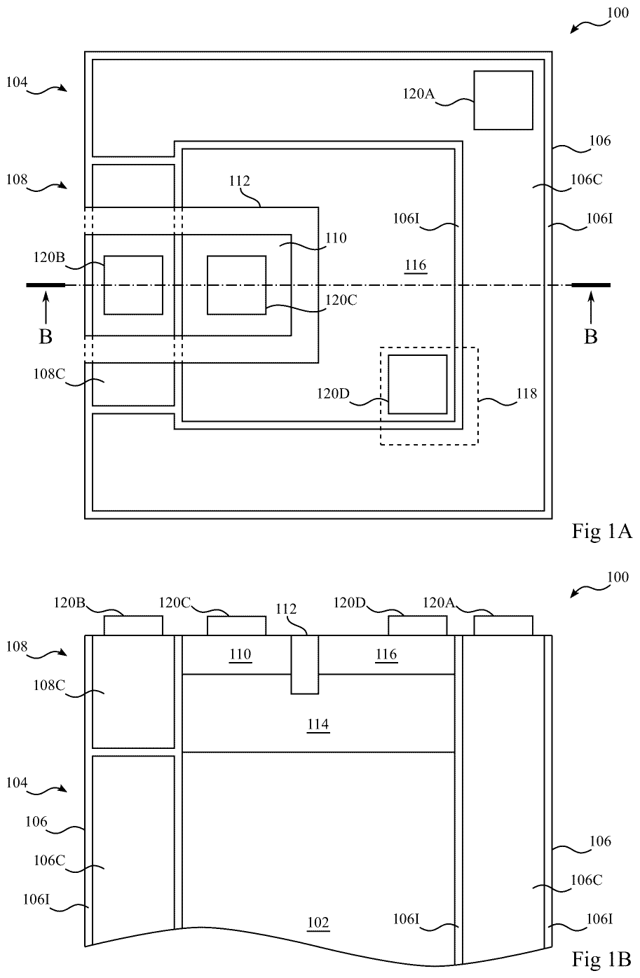

FIG. 1A and FIG. 1B are simplified and partial views, respectively a top view and a cross-section view along plane BB of FIG. 1A, of an example of an image sensor pixel 100 according to an embodiment.

In the shown example, pixel 100 comprises a photosensitive area 102, or photoconversion area. Photosensitive area 102 is for example intended to collect photons, during phases of illumination of the image sensor having pixel 100 belonging thereto, and to convert these photons into electron-hole pairs. Photosensitive area 102 is located, in top view, at the center of pixel 100 and has a substantially square-shaped periphery. This example is however not limiting, and photosensitive area 102 may as a variant have a periphery having any shape, for example rectangular or circular.

Photosensitive area 102 is formed in a substrate 104. Substrate 104 is made of a semiconductor material, for example silicon. As an example, substrate 104 is formed by epitaxial growth, or epitaxy, of a layer made of a semiconductor material on the side of a surface of a wafer or of a piece of a wafer of semiconductor material, for example silicon. As an example, substrate 104 has a thickness in the range from 1 to 20 μm.

Substrate 104 is doped with a first conductivity type, for example type N. In this case, substrate 104 is for example doped with arsenic atoms. As an example, substrate 104 has a doping level or rate in the range from 1×10¹⁰ to 1×10¹⁸ at./cm³.

The photosensitive area is for example intended to be illuminated from a lower side of substrate 104, in the orientation of FIG. 1B. As a variant, the photosensitive area may be intended to be illuminated from an upper side of substrate 104, in the orientation of FIG. 1B. Although this has not been illustrated in FIG. 1B, the lower side of substrate 104 may be coated with one or a plurality of passivation layers. Further, pixel 100 may comprise, on the lower surface side of substrate 104, optical elements such as a filter, for example a color filter, and/or a microlens.

In the shown example, pixel 100 comprises a peripheral insulating trench 106, for example a capacitive insulating trench, laterally delimiting photosensitive area 102. As an example, peripheral insulating trench 106 is a trench of capacitive deep trench insulation (CDTI) type. In top view, peripheral insulating trench 106 has a ring shape completely surrounding photosensitive area 102 on all its side walls, or flanks. Peripheral insulating trench 106 has a periphery identical in shape to that of photosensitive area 102, that is, square-shaped, in the shown example. This example is however not limiting, and peripheral insulating trench 106 may as a variant have a periphery of any shape, for example rectangular or circular. In the shown example, peripheral insulation trench 106 comprises four parts respectively corresponding to the four sides of the square formed by trench 106.

Peripheral insulating trench 106 enables in particular to electrically insulate the photosensitive area 102 of pixel 100 from the photosensitive areas of neighboring pixels, not shown in FIGS. 1A and 1B. Peripheral insulating trench 106 is formed, for example, in substrate 104. In the orientation of FIG. 1B, peripheral insulating trench 106 extends vertically across the thickness of substrate 104, from an upper surface of substrate 104 to the lower surface of substrate 104. In other words, in this example, peripheral insulating trench 106 extends vertically across the entire thickness of substrate 104.

Peripheral insulating trench 106 for example has a width in the range from 20 to 300 nm, for example equal to approximately 160 nm, and a depth in the range from 10 to 20 μm. In the example illustrated in FIG. 1B, peripheral insulating trench 106 has a depth equal to the thickness of substrate 104.

In the shown example, peripheral insulating trench 106 comprises an electrically-conductive region 106C. As an example, the electrically-conductive region 106C of peripheral insulating trench 106 is made of polysilicon, of a metal, for example copper, or of a metal alloy. In the case where region 106C is made of polysilicon, region 106C for example has a doping rate greater than or equal to 1×10¹⁸ at./cm³.

Peripheral insulating trench 106 further comprises, in this example, an electrically-insulating layer 106I coating the side walls of electrically-conductive region 106C. Electrically-insulating layer 106I electrically insulates electrically-conductive region 106C from substrate 104. As an example, electrically-insulating layer 106I is made of a dielectric material, for example of silicon oxide.

In the shown example, pixel 100 further comprises a vertical transfer gate 108 formed inside of peripheral insulating trench 106. Vertical transfer gate 108 is for example located, in top view, in one of the sides of the square formed by peripheral insulating trench 106 (the left-hand side, in the orientation of FIG. 1B). In the illustrated example, vertical transfer gate 108 comprises an electrically-conductive region 108C vertically extending across the thickness of substrate 104, from the upper surface of substrate 104, down to a depth smaller than that of peripheral insulating trench 106. As an example, vertical transfer gate 108 has a depth, or height, in the range from 0.2 to 1.5 μm.

The electrically-conductive region 108C of vertical transfer gate 108 is electrically insulated from the electrically-conductive region 106C of peripheral insulating trench 106. In the illustrated example, the side walls and the bottom of the electrically-conductive region 108C of vertical transfer gate 108 are coated with the electrically-insulating layer 106I of peripheral insulating trench 106. Further, in this example, the electrically-conductive region 108C of vertical transfer gate 108 is flush with the upper surface of substrate 104. As an example, the electrically-conductive region 108C of vertical transfer gate 108 is made of polysilicon, of a metal, for example copper, or of a metal alloy. In the case where region 108C is made of polysilicon, region 108C for example has a doping level greater than or equal to 1×10¹⁸ at./cm³.

In the illustrated example, pixel 100 further comprises a charge collection area 110 vertically extending in semiconductor substrate 104, from its upper surface, down to a depth smaller than that of the electrically-conductive region 108C of vertical transfer gate 108. In the shown example, charge collection area 110 has, in top view, a substantially square-shaped periphery. This example is however not limiting, and charge collection area 110 may have, as a variant, a periphery having any shape, for example rectangular or circular. As an example, the square formed by charge collection area 110 has a side length in the range from 100 to 200 nm, for example equal to approximately 170 nm.

In the shown example, charge collection area 110 is surrounded by an electrically-insulating trench 112. Insulating trench 112 extends vertically in semiconductor substrate 104, from its upper surface, down to a depth greater than that of charge collection area 110 and smaller than that of the electrically-conductive region 108C of vertical transfer gate 108. In the illustrated example, electrically-insulating trench 112 coats three of the four lateral surfaces of charge collection area 110, the fourth lateral surface of charge collection area 110 being covered with the electrically-insulating layer 106I of peripheral insulating trench 106. Insulating trench 112 is for example based on an oxide, for example silicon oxide. As an example, insulating trench 112 has a width equal to approximately 40 nm.

Charge collection area 110 is doped with the first conductivity type (type N, in this example) and has, for example, a doping level higher than that of photosensitive area 102. As an example, the doping level of charge collection area 110 is in the range from 1×10¹⁶ to 5×10²⁰ at./cm³.

In the illustrated example, pixel 100 further comprises a transfer region 114 formed in substrate 104 and vertically extending between charge collection area 110 and photosensitive area 102. Transfer region 114 extends, for example, across the thickness of substrate 104 down to a depth substantially equal to that of the conductive region 108C of transfer gate 108. In the shown example, transfer region 114 has, in top view, a substantially square-shaped periphery. This example is however not limiting, and transfer region 114 may as a variant have a periphery having any shape, for example, rectangular or circular. In the illustrated example, three of the four sides of the square formed by transfer region 114 are laterally bordered by peripheral insulating trench 106, and the fourth side of transfer region 114 is essentially laterally bordered by vertical transfer gate 108.

According to an embodiment, transfer region 114 is doped with the first conductivity type (type N, in this example) and has a doping level lower than that of photosensitive area 102. Further, the doping level of transfer region 114 is, for example, lower than that of charge collection area 110. As an example, transfer region 114 has a doping level in the range from 1×10¹⁰ to 9×10¹⁷ at./cm³.

Advantageously, the highest possible doping level gradient is formed at the interface between photosensitive area 102 and transfer region 114 (so-called “abrupt” interface). Further, in the shown example, the interface between transfer region 114 and photosensitive area 102 is substantially horizontal and located at a depth approximately equal to the depth down to which vertical transfer gate 108 extends. An N-type doping of photosensitive area 102, of transfer region 114, and of charge collection area 110 is preferred, since the atoms used to obtain an N-type doping, for example arsenic atoms, diffuse less than the atoms used to a obtain P-type doping, for example boron atoms. The fact of providing for photosensitive area 102, transfer region 114, and charge collection area 110 to be N-type doped advantageously enables to obtain an interface between photosensitive area 102 and transfer region 114 more abrupt than in the case of a P-type doping. The diffusion of boron atoms could however be limited by using reduced thermal budgets on manufacturing of pixel 100, or by introducing chemical elements enabling to block the diffusion of boron atoms.

In the shown example, pixel 100 further comprises a well 116 vertically extending across the thickness of substrate 104, from its upper surface, down to a depth smaller than that of vertical transfer gate 108, for example down to a depth substantially equal to that of charge collection area 110. In the illustrated example, well 116 is laterally bordered by peripheral insulating trench 106 and by insulating trench 112, the insulating trench being laterally interposed between charge collection area 110 and well 116. Well 116 is doped with a second conductivity type, opposite to the first conductivity type (type P, in this example). In the case where well 116 is P-type doped, the doping is for example obtained by boron atoms. As an example, well 116 has a doping level in the range from 1×10¹⁶ to 1×10¹⁹ at./cm³.

In the shown example, insulating trench 112 advantageously enables to avoid or to attenuate field effects between charge collection area 110 and well 116.

In the illustrated example, pixel 100 comprises another well 118 formed in well 116 and vertically extending across the thickness of substrate 104, from its upper surface, down to a depth smaller than that of well 116. Well 118 is formed in one of the corners of well 116 opposite to vertical transfer gate 108. In practice, well 118 may laterally extend, as in the shown example, inside of peripheral insulating trench 106. Well 118 is doped with the second conductivity type (type P, in this example) and has a doping level higher than that of well 116. As an example, the doping level of well 118 is in the range from 1×10¹⁷ to 5×10²⁰ at./cm³.

In the shown example, pixel 100 further comprises contacting elements 120A, 120B, 120C, and 120D, for example conductive pads, respectively formed on top of and in contact with the conductive region 106C of peripheral insulating trench 106, the conductive region 108C of vertical transfer gate 108, charge collection area 110, and well 118. In the illustrated example, each contacting element 120A, 120B, 120C, 120D has, in top view, a substantially square-shaped periphery. This example is however not limiting, and each contacting element 120A, 120B, 120C, 120D may as a variant have a periphery of any shape, for example rectangular or circular. Contacting elements 120A, 120B, 120C, and 120D are made of an electrically-conductive material, for example a metal, for example copper, or a metal alloy. As an example, each contacting element 120A, 120B, 120C, 120D has a maximum lateral dimension (for example, a side length, in the shown example where each contacting element is square-shaped) equal to approximately 90 nm.

During a phase of exposure, or of accumulation, of pixel 100, electron-hole pairs are for example created within photosensitive area 102. During this phase, the electrically-conductive region 106C of peripheral insulating trench 106 and the electrically-conductive region 108C of vertical transfer gate 108 are respectively taken to potentials V_CDTI and V_TG_OFF. In the shown example, potentials V_CDTI and V_TG_OFF are applied by means of contacting elements 120A and 120B, respectively. Potential V_TG_OFF is, for example, substantially equal to potential V_CDTI. During the exposure phase, the application of potentials V_CDTI and V_TG_OFF to electrically-conductive regions 106C and 108C enables to form a potential barrier in transfer region 114, between photosensitive area 102 and charge collection area 110. In the shown example, transfer region 114 is bordered by the inner side walls of peripheral insulating trench 106 and of vertical transfer gate 108, and vertically extends, across the thickness of substrate 104, under charge collection area 110. In other words, the potential barrier jointly formed by peripheral insulating trench 106 and vertical transfer gate 108 laterally extends, in top view, over the entire surface of transfer region 114.

The presence of the potential barrier in transfer region 114 enables, during the exposure phase, to block a transfer of photogenerated carriers (electrons, in the case where photosensitive area 102, transfer region 114, and charge collection area 110 are of type N) from photosensitive area 102 to charge collection area 110. This potential barrier results from the presence, along the side walls of peripheral insulating trench 106 and of transfer gate 108, of an inversion layer attracting carriers of the opposite type towards the substrate (holes, in this example).

During the exposure phase, charge collection area 110 and well 118 are respectively taken to potentials V_SN and V_WELL. In the shown example, potentials V_SN and V_WELL are applied by means of contacting elements 120C and 120D, respectively. Contacting element 120D for example enables to supply the charge carriers enabling to form the potential barrier inside of transfer region 114 during the exposure phase.

During a readout phase subsequent to the exposure phase, the electrically-conductive region 108C of vertical transfer gate 108 is for example taken to a potential V_TG_ON different from potential V_TG_OFF, the electrically-conductive region 106C of the peripheral insulating trench 106 being maintained at potential V_CDTI. During the readout phase, the application of potential V_TG_ON to electrically-conductive region 106C enables to lower, or even to remove, the potential barrier in transfer region 114 between photosensitive area 102 and charge collection area 110. The disappearing of the potential barrier enables, during the readout phase, a transfer of the photogenerated charges from photosensitive area 102 to charge collection area 110.

As an example, the image sensor comprising pixel 100 further comprises a control circuit configured to alternately apply, to the contacting element 120B connected to the conductive region 108C of transfer gate 108:
potential V_TG_OFF adapted to blocking a charge transfer from photosensitive area 102 to charge collection area 110; and
potential V_TG_ON adapted to allowing a charge transfer from photosensitive area 102 to charge collection area 110.

During the readout phase, charge collection area 110 and well 118 are for example respectively held at potentials V_SN and V_WELL. Although this has not been detailed in FIGS. 1A and 1B, contacting element 120C is for example connected to a readout circuit, for example located on the upper surface side of substrate 104. Contacting element 120C is for example more specifically connected to a sense node, not shown, and enables to transfer charges accumulated in charge collection area 110 to the sense node.

As an example:
in the case where photosensitive area 102, transfer region 114, and charge collection area 110 are of type N and wells 116 and 118 are of type P:
   potential V_TG_ON is equal to approximately 1.8 V;
   potential V_TG_OFF is equal to approximately-0.5 V;
   potential V_CDTI is equal to approximately-0.5 V;
   potential V_WELL is equal to approximately 0.2 V; and potential V_SN is equal to approximately 1.8 V, and—in the case where photosensitive area 102, transfer region 114 and charge collection area 110 are of type P and wells 116 and 118 are of type N:
   potential V_TG_ON is equal to 0 V;
   potential V_TG_OFF is equal to approximately 1.8 V;
   potential V_CDTI is equal to approximately 1.8 V;
   potential V_WELL is equal to approximately 1.5 V; and
   potential V_SN is equal to approximately 0.5 V.

In the above example, potential V_TG_ON is equal to potential V_SN. This example is however not limiting, and potential V_TG_ON may, as a variant, be different from potential V_SN.

In a sensor comprising a plurality of pixels arranged in an array of rows and columns, there is designated as “pixel pitch” the center-to-center distance between two adjacent pixels in the row or column direction. The pixel pitch in the row or column direction substantially corresponds to the lateral dimension of the pixel in said direction.

An advantage of the sensor integrating pixels of the type of the pixel 100 described above is that it may have a pixel pitch, in the row direction and in the column direction, smaller than that of existing sensors, for example smaller than 1 μm, for example in the range from 0.6 to 0.8 μm.

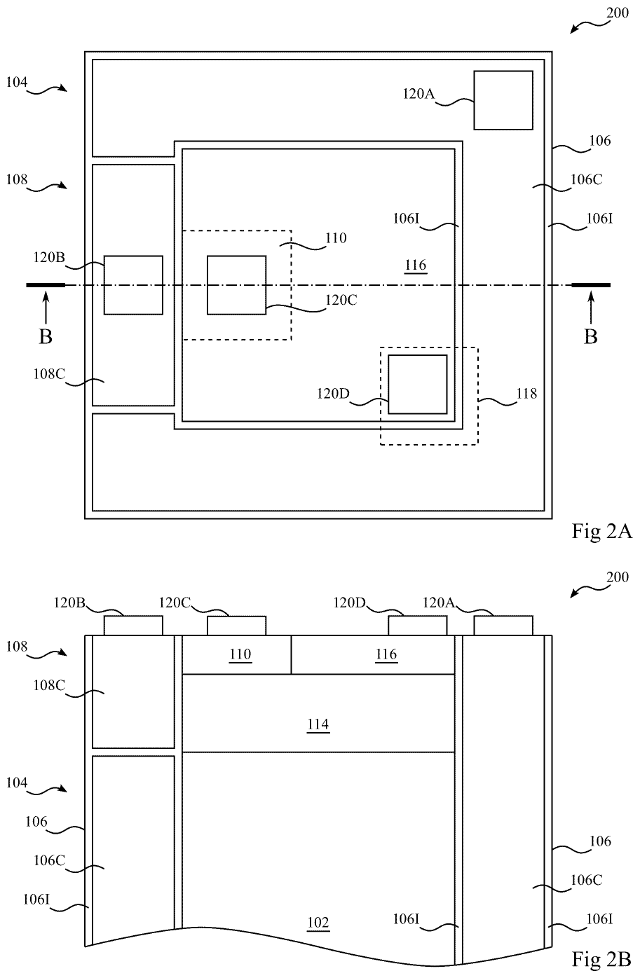

FIG. 2A and FIG. 2B are simplified and partial views, respectively a top view and a cross-section view along plane BB of FIG. 2A, of an example of an image sensor pixel 200 according to an embodiment.

The pixel 200 of FIGS. 2A and 2B comprises elements in common with the pixel 100 of FIGS. 1A and 1B. These common elements will not be detailed again hereafter. The pixel 200 of FIGS. 2A and 2B differs from the pixel 100 of FIGS. 1A and 1B in that pixel 200 does not comprise electrically-insulating trench 112. This eases the forming of pixel 200 as compared with pixel 100.

In this example, charge collection area 110 and well 116 are adjacent. This example is however not limiting, and charge collection area 110 may, as a variant, be separated from well 116 by a portion of transfer region 114 laterally extending between area 110 and well 116. This advantageous enables to decrease an electric field causing a dark current.

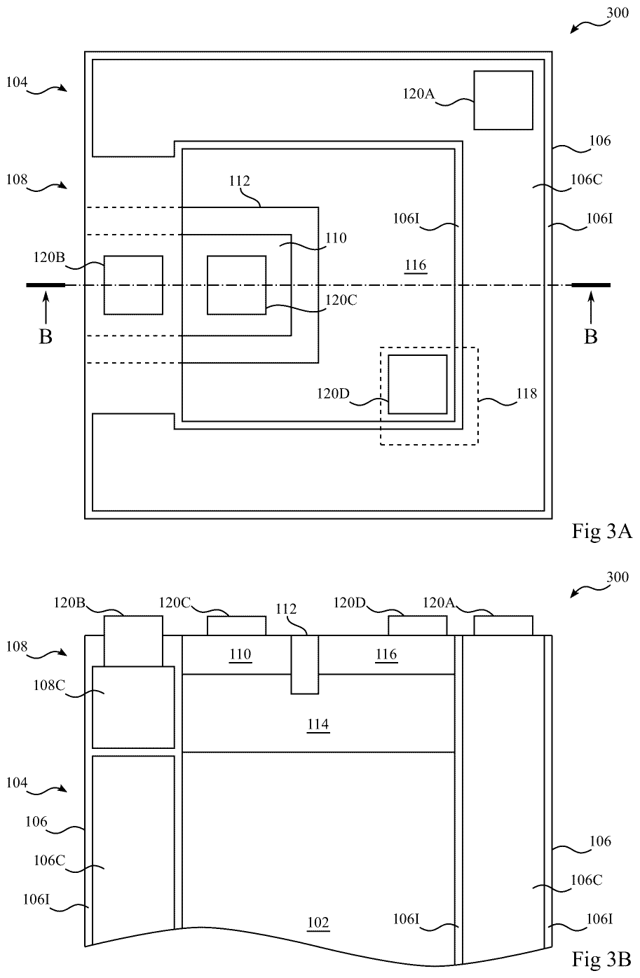

FIG. 3A and FIG. 3B are simplified and partial views, respectively a top view and a cross-section view along plane BB of FIG. 3A, of an example of an image sensor pixel 300 according to an embodiment.

The pixel 300 of FIGS. 3A and 3B comprises elements in common with the pixel 100 of FIGS. 1A and 1B. These common elements will not be detailed again hereafter. The pixel 300 of FIGS. 3A and 3B differs from the pixel 100 of FIGS. 1A and 1B in that the electrically-conductive region 108C of the vertical transfer gate 108 of pixel 300 is separated from the upper surface of substrate 104 by a non-zero thickness of electrically-insulating material, for example an oxide, for example the material of the insulating layer 106I of peripheral insulating trench 106. In other words, the electrically-conductive region 108C of the transfer gate 108 of pixel 300 is not flush with the upper surface of substrate 104. This advantageously enables to decrease a capacitance between the conductive region 108C of vertical transfer gate 108 and charge collection area 110 as compared with the case of pixel 100.

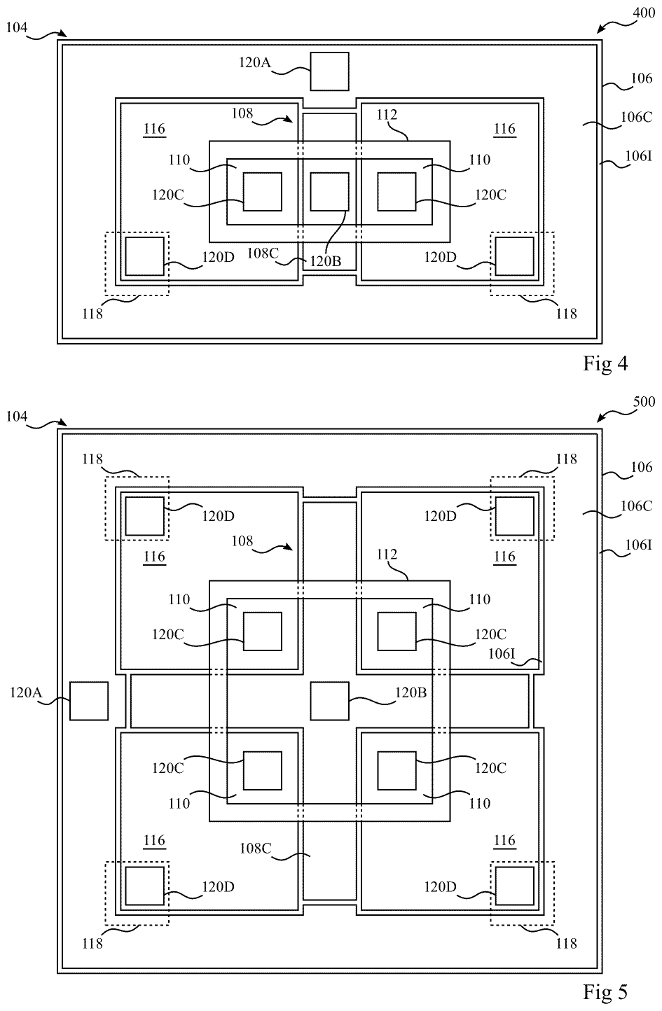

FIG. 4 is a top view, simplified and partial, of an arrangement 400 of two adjacent pixels 100 according to an embodiment.

In the shown example, the two pixels 100 are juxtaposed so that they share a portion of peripheral insulating trench 106. In the orientation of FIG. 4, the left-hand pixel 100 is symmetrical to the right-hand pixel 100 with respect to a vertical axis. Vertical transfer gate 108 is formed in the portion of peripheral insulating trench 106 common to the two pixels 100. This enables to decrease the surface area occupied by the pixels of the image sensor.

In the shown example, insulating trench 112 is common to the two pixels 100 and surrounds contacting element 120B, located at the center of arrangement 400, and the two contacting elements 120C located on either side of vertical transfer gate 108. Further, the two pixels 100 of arrangement 400 comprise, for example, a single conductive pad 120A.

In the arrangement 400 of FIG. 4, transfer gate 108 is common to the two pixels 100 and allows a simultaneous blocking and transfer, from the photosensitive areas 102 to the charge collection areas 110 of pixels 100, of the charges photogenerated in these pixels.

FIG. 5 is a top view, simplified and partial, of an arrangement 500 of four adjacent 100 pixels according to an embodiment.

In the shown example, the four pixels 100 are juxtaposed so that they share portions of peripheral insulating trench 106. In the orientation of FIG. 5, the left-hand pixels 100 are symmetrical to the right-hand pixels 100 with respect to a vertical axis, and the upper pixels 100 are symmetrical to the lower pixels 100 with respect to a horizontal axis. Vertical transfer gate 108 is formed in the portions of peripheral insulating trench 106 common to the four pixels 100, and has, in top view, a cross shape (+). This enables to even further decrease the surface area occupied by the image sensor pixels.

In the shown example, insulating trench 112 is common to the four pixels 100 and surrounds contacting element 120B, located at the center of arrangement 500, and the four contacting elements 120C. Further, the four pixels 100 of arrangement 500 comprise, for example, a single conductive pad 120A.

In the arrangement 500 of FIG. 5, transfer gate 108 is common to the four pixels 100 and allows a simultaneous blocking and transfer, from the photosensitive areas 102 to the charge collection areas 110 of pixels 100, of the charges photogenerated in these pixels.

Various embodiments and variants have been described. Those skilled in the art will understand that certain features of these various embodiments and variants may be combined, and other variants will occur to those skilled in the art. In particular, the embodiment of the pixel 200 of FIGS. 2A and 2B and the embodiment of the pixel 300 of FIGS. 3A and 3B may be combined, so as to obtain a pixel comprising no insulating trench 112 and in which the electrically-conductive region 108C of vertical transfer gate 108 is separated from the upper surface of substrate 104 by a non-zero thickness of electrically-insulating material.

Further, although arrangements 400 and 500 have been described hereabove in a case where they comprise pixels 100, similar arrangements may be provided with pixels 200, with pixels 300, or with pixels combining the characteristics of pixels 200 and 300 as indicated hereabove. Such arrangements are within the abilities of those skilled in the art based on the indications of the present disclosure.

Further, although the described embodiments take as an example the case where photosensitive area 102, transfer region 114, and charge collection area 110 are N-type doped while wells 116 and 118 are P-type doped, those skilled in the art are capable, based on the indications of the present disclosure, of transposing these embodiments to the case where the doping types are reversed, that is, photosensitive area 102, transfer region 114, and charge-collection zone 110 are P-type doped while wells 116 and 118 are N-type doped.

Finally, the practical implementation of the described embodiments and variants is within the abilities of those skilled in the art based on the functional indications given hereabove. In particular, the described embodiments are not limited to the specific examples of materials and of dimensions mentioned in the present disclosure.

1. Image sensor comprising a plurality of pixels formed inside and on top of a semiconductor substrate, each pixel comprising:
a photosensitive area formed in the semiconductor substrate;
a peripheral insulating trench vertically extending in the semiconductor substrate, from an upper surface of the semiconductor substrate, and laterally delimiting the photosensitive area;
a charge collection area;
a transfer region located in the semiconductor substrate and vertically extending between the charge collection area and the photosensitive area; and
a transfer gate vertically extending in the semiconductor substrate, from the upper surface of the semiconductor substrate and inside of the peripheral insulating trench, deeper than the charge collection area,
wherein the transfer region is doped with a same first conductivity type as the photosensitive area and has a doping level lower than that of the photosensitive area.

2. Sensor according to claim 1, wherein the transfer gate vertically extends in the semiconductor substrate down to a depth substantially equal to that of the transfer region.

3. Sensor according to claim 1, wherein the photosensitive area and the transfer region have a substantially horizontal interface.

4. Sensor according to claim 1, wherein the charge collection area is doped with the first conductivity type and has a doping level higher than that of the transfer region.

5. Sensor according to claim 1, further comprising a doped well of a second conductivity type opposite to the first conductivity type, the well vertically extending in the semiconductor substrate, from the upper surface of the semiconductor substrate, down to a depth smaller than that of the transfer gate.

6. Sensor according to claim 5, further comprising an electrically-insulating trench laterally interposed between the charge collection area and the well.

7. Sensor according to claim 6, wherein the electrically-insulating trench vertically extends in the semiconductor substrate, from the upper surface of the semiconductor substrate, down to a depth greater than that of the charge collection area.

8. Sensor according to claim 5, wherein the charge collection area and the well are adjacent.

9. Sensor according to claim 1, wherein the peripheral insulating trench and the transfer gate respectively comprise first and second electrically-conductive regions, the first electrically-conductive region being electrically insulated from the second electrically-conductive region.

10. Sensor according to claim 9, wherein the second electrically-conductive region is flush with the upper surface of the semiconductor substrate.

11. Sensor according to claim 9, wherein the second electrically-conductive region is separated from the upper surface of the semiconductor substrate by a non-zero thickness of insulating material.

12. Sensor according to claim 1, wherein the transfer gate is common to two pixels.

13. Sensor according to claim 1, wherein the transfer gate is common to four pixels.

14. Sensor according to claim 1, wherein the first conductivity type is type N.

15. Sensor according to claim 1, further comprising a control circuit configured to alternately apply, to the transfer gate:
a first potential adapted to blocking a charge transfer from the photosensitive area to the charge collection area; and
a second potential, different from the first potential, adapted to allowing a charge transfer from the photosensitive area to the charge collection area.
